(19) United States
(12) Patent Application Publication
(10) Pub. No.: US 2022/0225551 A1
(43) Pub. Date: Jul. 14, 2022

(54) ELECTROMAGNETIC WAVES ABSORBING MATERIAL

(71) Applicant: BASF SE, Ludwigshafen (DE)

(72) Inventors: Erik Gubbels, Ludwigshafen (DE); Ingolf Hennig, Ludwigshafen (DE); Martina Schoemer, Ludwigshafen (DE); Peter Eibeck, Speyer (DE)

(21) Appl. No.: 17/609,435

(22) PCT Filed: May 27, 2020
(86) PCT No.: PCT/EP2020/064697

§ 371 Date: Nov. 8, 2021

(30) Foreign Application Priority Data
Jun. 5, 2019 (DE) 10 2019 006 227.2

(51) Int. Cl. H05K 9/00; C08K 3/04; C08K 3/08

(52) U.S. Cl. CPC H05K 9/0083; H05K 9/009; C08K 2003/0856; C08K 3/08; C08K 3/04

(57) ABSTRACT

The present invention relates to an electromagnetic millimetre wave absorber material, preferably having a volume resistivity of more than 1 Ω cm, containing solid particles having an aspect ratio (length:diameter) of at least 5 of a first electrically conductive material, particles having an aspect ratio (length:diameter) of less than 5 of a second electrically conductive material and an electrically non-conductive polymer, wherein the absorber material is capable of absorbing electromagnetic waves in a frequency region of 60 GHz or more. The invention also relates to its use and method for absorbing as well as a sensor apparatus comprising said absorber material.

The present invention relates to an electromagnetic millimetre wave absorber material, preferably having a volume resistivity of more than 1 Ωcm, containing solid particles having an aspect ratio (length:diameter) of at least 5 of a first electrically conductive material, particles having an aspect ratio (length:diameter) of less than 5 of a second electrically conductive material and an electrically non-conductive polymer, wherein the absorber material is capable of absorbing electromagnetic waves in a frequency region of 60 GHz or more. The invention also relates to its use and method for absorbing as well as a sensor apparatus comprising said absorber material.

Current engineering plastics cannot be used for the application of absorption of electromagnetic radiation in a frequency range of 60-90 GHz. Current materials are transparent for this type of radiation or reflect significant amounts. The aim of the absorbing material is to lower the electromagnetic interference on the sensor, by the absorption of unwanted electromagnetic radiation. A current solution is available as semi-finished goods from which the right size sample needs to be cut out. This is an undesirable process, since it creates much more waste and the geometry of the samples is limited to 2 dimensional semi-finished goods. A solution which can be injection molded is much more desirable.

JP 2017/118073 A2 describes an electromagnetic wave absorbing material capable of absorbing electromagnetic waves in a high frequency region of 20 GHz or more. The electromagnetic wave absorbing material contains an insulating material and a conductive material and has a volume resistivity of 10⁻² Ω·cm or more and less than 9×10⁵ Ω·cm. The electromagnetic wave absorbing material is provided as a film containing carbon nanotubes. However, nanotubes are difficult to handle due to toxicity reasons. In addition, carbon nanotubes are expensive. Carbon nanotubes are also described in WO 2012/153063 A1.

Also U.S. Pat. No. 4,606,848 A describes a film-like composition in form of a paint in a lower GHz frequency range unsuitable for autonomous driving, wherein a radar attenuating paint composition for absorbing and scattering incident microwave radiation is described having a binder composition with a plurality of dipole segments made of electrically conductive fibers uniformly dispersed therein.

Also WO 2010/109174 A1 describes a film-like composition as dried coating derived from an electromagnetic radiation absorbing composition comprising a carbon filler comprising elongate carbon elements with an average longest dimension in the range of 20 to 1000 microns, with a thickness in the range of 1 to 15 microns and a total carbon filler content in the range of from 1 to 20 volume % dried, in a nonconductive binder.

Also WO 2017/110096 A1 describes an electromagnetic wave absorber with a plurality of electromagnetic wave absorption layers each including carbon nanostructures and an insulating material. F. Quin et al., Journal of Applied Physics 111, 061301 (2012), give an overview of microwave absorption in polymer composites filled with carbonaceous particles.

US 2011/168440 A1 described an electromagnetic wave absorbent which contains a conductive fiber sheet which is obtained by coating a fiber sheet base with a conductive polymer and has a surface resistivity within a specific range. The conductive fiber sheet is formed by impregnating a fiber sheet base such as a nonwoven fabric with an aqueous oxidant solution that contains a dopant, and then bringing the resulting fiber sheet base into contact with a gaseous monomer for a conductive polymer, so that the monomer is oxidatively polymerized thereon.

JP 2004/296758 A1 described a plate-like millimeter wave absorber having an absorbing layer laminated on a reflective layer. The absorbent layer has a thickness of 1.0 mm to 5.0 mm and contains 1 to 30 parts by weight of carbon black with respect to 100 parts by weight of a resin of a resin or a rubber.

JP 2004/119450 A1 describes a radio wave absorbing layer made of a composite material containing carbon short fibers and nonconductive short fibers and a resin and a radio wave reflecting layer provided on the back surface of the radio wave absorbing layer and in a frequency range of 2 to 20 GHz.

JP H11-87117 A describes a high frequency electromagnetic wave absorber characterized by dispersing a soft magnetic flat powder having a thickness of 3 μm or less in an insulating base material.

US 2003/0079893 A1 describes a radio wave absorber with a radio wave reflector and at least two radio wave absorbing layers disposed on a surface of the radio wave reflector, the at least two radio wave absorbing layers being formed of a base material and electroconductive titanium oxide mixed with the base material. The radio wave absorbing layers have different blend ratios of the electroconductive titanium oxide so as to make their radio wave absorption property different.

A. Dorigato et al., Advanced Polymer Technology 2017, 1-11, describe synergistic effects of carbon black and carbon nanotubes on the electrical resistivity of poly(butylene-terephthalate) nanocomposites.

S. Motojima et al., Letters to the Editor, Carbon 41 (2003) 2653-2689, describe electromagnetic wave absorption properties of carbon microcoils/PMMA composite beads in W-bands (see also S. Motojima et al., Transactions of the Materials Research Society of Japan (2004), 29(2), 461-464).

Such approaches mostly use constructional elements with layered absorber instead of providing said elements having suitable absorber properties as such. Also expensive components are used and absorbers are described for different frequency ranges.

Thus, there is a need to provide absorber material that shows good absorption and reflection properties and that can be used as constructional element having also good mechanical properties (e.g. tensile strength).

Accordingly, an object of the present invention is to provide such material and sensors.

This object is achieved by an electromagnetic millimetre wave absorber material, preferably having a volume resistivity of more than 1 Ωcm, containing solid particles having an aspect ratio (length:diameter) of at least 5 of a first electrically conductive material, particles having an aspect ratio (length:diameter) of less than 5 of a second electrically conductive material and an electrically non-conductive polymer, wherein the absorber material is capable of absorbing electromagnetic waves in a frequency region of 60 GHz or more.

The object is also achieved by an electronic device containing a radar absorber in form of a radar absorber part or a radar absorbing housing, the radar absorber comprising
at least an absorber material of the present invention, wherein the at least one absorber material is comprised in the electronic device in the radar absorber;
at least one transmission area, transmissible for electromagnetic millimeter waves in a frequency region of 60 GHz or more; and
a sensor capable of detecting and optionally emitting electromagnetic millimeter waves in a frequency region of 60 GHz or more through the transmission area.

The object is also achieved by the use an absorber material of the present invention for the absorption of electromagnetic millimeter waves in a frequency region of 60 GHz or more.

The object is also achieved by a method of absorbing electromagnetic millimeter waves in a frequency region of 60 GHz or more, the method comprising the step of irradiating an absorber material of the present invention with electromagnetic millimeter waves in a frequency region of 60 GHz or more.

Unexpectedly, the solution to this problem is the addition of electrically conductive fillers, preferably to an injection moldable matrix, where fibrous additives were combined with certain particulates. This leads to an increase of the absorption where this was not possible if a same amount of one type of fibers were added. This solution yields a low transmission, without a high reflection and with high absorption with different additives in various polymeric matrices in a frequency region of 60 GHz or more. Dielectric parameters show strong frequency dependence, therefore not easy to expand to other frequency ranges. Different dielectric relaxation mechanisms are occurring depending on the frequency range. Advantageously, non-conductive fillers can be used to improve tensile strength and surprisingly even in fibrous or particulate form without affecting the absorption and reflection properties.

The absorber material of the present invention is capable of absorbing electromagnetic waves in a frequency region of 60 GHz or more, preferably in the range of 60 GHz to 90 GHz, more preferably in the range from 76 GHz to 81 GHz. Thus, the absorber material of the present invention represents an electromagnetic millimeter wave absorber.

The absorber material of the present invention contains solid particles of a first electrically conductive material. The term “solid” means that the particles do not have any pipe-like channels, like carbon nanotubes. For avoidance of any doubt the term “solid” should not be interpreted to exclude porous material. The term solid is especially defined as to exclude carbon nanotubes.

The solid particles of the first conductive material have an aspect ratio (length:diameter) of at least 5. In case of a straight form of the particles the length correlates with the longitudinal distance. However, the particles can also show a curved or spiral form. For such geometries the contour length is used. Preferably, the solid particles have an aspect ratio (length:diameter) of at least 7, more preferably at least 10. Preferably at least the first electrically conductive material are solid fibre particles have an acicular or cylindrical shape or a turned chip like shape. The solid particles should having regular or irregular shape. It is possible that solid fibre particles having an acicular or cylindrical shape or a turned chip like shape with an aspect ratio of less than 5 can be present in the absorber material.

The absorber material of the present invention also contains particles of a second electrically conductive material. The first and second electrically conductive material can be the same or different materials. However, the particles of the second electrically conductive material and the particles of the first conductive material show different shape and thus can be differentiated.

The particles of the second electrically conductive material have an aspect ratio (length:diameter) of less than 5, preferably, less than 3. Preferably, the particles are non-fibrous particles having a spherical or lamellar shape.

The absorber material of the present invention also contains an electrically non-conductive polymer. This polymer can be a homopolymer, a copolymer or a mixture of two or more, like three four or five, homo- and/or copolymers. Preferably, the electrically non-conductive polymer is a thermoplast, thermoplastic elastomers, thermoset or a vitrimer, preferably a thermoplastic material and more preferably a polycondensate, more preferably a polyester and most preferably poly(butylene terephthalate).

Examples of the electrically non-conductive polymer are an epoxy resin, a polyphenylene sulfide, a polyoxymethylene, an aliphatic polyketone, a polyaryl ether ketone, a polyether ether ketone, a polyamide, a polycarbonate, a polyimide, a cyanate ester, a terephthalate, like poly(butylene terephthalate) or poly(ethylene terephthalate) or poly(trimethylene terephthalate), a poly(ethylene naphthalate), a bismaleimide-triazine resin, a vinyl ester resin, a polyester, a polyaniline, a phenolic resin, a polypyrrole, a polymethyl methacrylate, a phosphorus-modified epoxy resin, a polyethylenedioxythiophene, polytetrafluoroethylene, a melamine resin, a silicone resin, a polyetherimide, a polyphenylene oxide, a polyolefin such as polypropylene or polyethylene or copolymers thereof, a polysulfone, a polyether sulfone, a polyarylamide, a polyvinyl chloride, a polystyrene, an acrylonitrile-butadiene-styrene, an acrylonitrile-styrene-acrylate, a styrene-acrylonitrile, or a mixture of two or more of the above mentioned polymers.

Preferably, the particles of the first and second electrically conductive material are homogenously distributed in the absorber material. This can be achieved by merely mixing the components together where the polymer is in the molten form or with or without solvent, i.e. as homogenous dispersion or in dry form.

The absorber material can be shaped in order to represent a constructional element, like an element of a sensor apparatus. Thus, in a preferred embodiment the absorber material of the present invention is subject to injection molding, thermoforming, compression molding or 3D printing, preferably injection molding. Methods for shaping are well-known in the art and a practitioner in the art can easily adopt method parameters in order to obtain the absorber material of the present invention as shaped element.

Preferably, the amount of the particles of the first and second electrically conductive material is from 0.05 wt.-% (present by weight) to 25 wt.-%, preferably 0.1 wt.-% to 25 wt.-%, preferably from 2 wt.-% to 22 wt.-%, more preferably from 5 wt.-% to 20 wt.-%, based on the total amount of the absorber material.

Preferably, the amount of the particles of the first electrically conductive material is from 0.05 wt.-% (present by weight) to 24.95 wt.-%, preferably 0.05 wt.-% (percent by weight) to 22 wt.-%, preferably from 1 wt.-% to 20 wt.-%, more preferably from 3 wt.-% to 19 wt.-%, based on the total amount of the absorber material.

Preferably, the amount of the particles of the second electrically conductive material is from 0.05 wt.-% to 24.95 wt.-%, preferably, 0.5 wt.-% to 15 wt.-%, based on the total amount of the absorber material.

Preferably, the first and second electrically conductive material is carbon or a metal. Accordingly, in a first aspect of the present invention the first and second electrically conductive material is carbon. In a second aspect of the present invention the first and second electrically conductive material is metal. In a third aspect of the present invention the first electrically conductive material is a metal and the second electrically conductive material is carbon. In a fourth aspect of the present invention, the first electrically conductive material is carbon and the second electrically conductive material is metal.

Preferably, the metal is zinc, nickel, copper, tin, cobalt, manganese, iron, magnesium, lead, chromium, bismuth, silver, gold, aluminum, titanium, palladium, platinum, tantalum, or an alloy thereof, preferably iron or an alloy, especially an iron alloy. Even more preferably, the iron or iron alloy material is stainless-steel.

Preferably, the first and the second electrically conductive material is the same, more preferably, the first and the second electrically conductive material is carbon.

In a further embodiment of the present invention, the first and the second electrically conductive material is different, more preferably the first electrically conductive material is iron or steel and the second conductive material is carbon.

Preferably, the particles of the second electrically conductive material are carbon black.

Preferably, the particles of the first electrically conductive material have a length of from 0.01 to 100 mm, preferably from 10 μm to 10 mm, even more preferably from 10 μm to 1000 μm, even more preferably from 50 μm to 750 μm, even more preferably from 100 μm to 500 μm.

Preferably, the particles of the first electrically conductive material have a diameter of from 0.1 μm to 100 μm, preferably from 1 μm to 100 μm, even more preferably from 2 μm to 70 μm, even more preferably from 3 μm to 50 μm, even more preferably from 5 μm to 40 μm.

In a further embodiment of the present invention the absorber material additionally contains at least one electrically non-conductive filler, preferably at least one fibrous or particulate filler, more preferably at least one fibrous filler, especially glass fibers.

In one embodiment of the present invention the absorber material of the present invention additionally contains a further filler component with one or more, like two three or four, further fillers. The fillers are different to the first and second electrically conductive material and the electrically non-conductive polymer. In a more specific embodiment of the present invention, the filler component contains at least one electrically non-conductive filler, preferably a fibrous or particulate filler.

Exemplary fillers are glass fibers, glass beads, amorphous silica, asbestos, calcium silicate, calcium metasilicate, magnesium carbonate, kaolin, chalk, powdered quartz, mica, barium sulfate and feldspar. Preferably, the filler component contains or consists of glass fibres. Typically, the additional filler component can be present in the absorber material of the present invention in an amount of up to 50% by weight, in particular up to 40% by weight and typically at least 1% by weight, preferably at least 5% by weight, more preferably at least 10% by weight, each based on the total amount of the absorber material.

Preferred fibrous electrically non-conductive fillers which may be mentioned are aramid fibers and Basalt fibers, wood fibers, quarz fibers, aluminum oxide fibers and particular preference is given to glass fibers in the form of E glass. These may be used as rovings or in the commercially available forms of chopped glass.

The fibrous fillers may have been surface-pretreated with a silane and further compounds, especially to improve compatibility with a thermoplastic.

Suitable silane compounds have the formula (X—(CH₂)ₙ)ₖ—Si—(O—CₘH₂ₘ₊₁)₄₋ₖ, where:

X is —NH₂, —OH or oxiranyl,
n is an integer from 2 to 10, preferably 3 or 4,
m is an integer from 1 to 5, preferably 1 or 2, and
k is an integer from 1 to 3, preferably 1.

Preferred silane compounds are aminopropyltrimethoxysilane, aminobutyltrimethoxysilane, aminopropyltriethoxysilane and aminobutyltriethoxysilane, and also the corresponding silanes which contain a glycidyl group as substituent X.

The amounts of the silane compounds generally used for surface-coating are from 0.05 to 5% by weight, preferably from 0.1 to 1% by weight and in particular from 0.2 to 0.8% by weight based on total amount of the fibrous filler.

Acicular mineral fillers are also suitable.

For the purposes of the present invention, acicular mineral fillers are mineral fillers with strongly developed acicular character. An example is acicular wollastonite. The mineral preferably has an aspect ratio of from 8:1 to 35:1, preferably from 8:1 to 11:1. The mineral filler may, if desired, have been pretreated with the abovementioned silane compounds, but the pretreatment is not essential.

Other fillers which may be mentioned are kaolin, calcined kaolin, talc and chalk.

The absorber material of the present invention may comprise usual molding processing aids as further fillers of the filler component, such as stabilizers, oxidation retarders, agents to counteract decomposition due to heat and decomposition due to ultraviolet light, lubricants and mold-release agents, colorants, such as dyes and pigments, nucleating agents, plasticizers, etc.

Examples which may be mentioned of oxidation retarders and heat stabilizers are sterically hindered phenols and/or phosphites, hydroquinones, aromatic secondary amines, such as diphenylamines, various substituted members of these groups, and mixtures of these in concentrations of up to 1.5% by weight, based on the weight of the absorber material of the present invention.

UV stabilizers which may be mentioned, and are generally used in amounts of up to 2% by weight, based on the absorber material, are various substituted resorcinol, salicylates, benzotriazoles, hindered amine light stabilizers and benzophenones.

Colorants which may be added are inorganic pigments, such as titanium dioxide, ultramarine blue, iron oxide, and carbon black, and also organic pigments, such as phthalocyanines, quinacridones and perylenes, and also dyes, such as nigrosine and anthraquinones.

Nucleating agents which may be used are sodium salts of weak acids and preferably talc.

Lubricants and mold-release agents which may be used in amounts of up to 1.5% by weight. Preference is given to long-chain fatty acids (e.g. stearic acid or behenic acid), salts of these (e.g. calcium stearate or zinc stearate), esters of these with fatty acid alcohols or multifunctional alcohols (e.g. glycerine, pentaerytrithol, trimethylol propane), amides from difunctional amines (e.g. ethylene diamine), or montan waxes (mixtures of straight-chain saturated carboxylic acids having chain lengths of from 28 to 32 carbon atoms), or calcium montanate or sodium montanate, or oxidized low-molecular-weight polyethylene waxes.

Hydrolysis stabilizers which may be used are carbodiimides like bis(2,6-diisopropylphenyl)carbodiimide, polycarbodiimides (e.g. Lubio® Hydrostab 2) or epoxides such as, adipic acid bis(3,4-epoxycylcohexylmethyl)ester, triglycidylisocyanurate, trimethylol propane tryglycidylether, epoxidize plant oils or prepolymers of bisphenol A and epychlorohydrine (especially required when polyesters are the electrically non-conductive polymer).

Examples of plasticizers which may be mentioned are dioctyl phthalates, dibenzyl phthalates, butyl benzyl phthalates, hydrocarbon oils and N-(n-butyl)benzene-sulfonamide.

Suitable additives that may be comprised in the absorber material of the present invention are described in US 2003/195296 A1.

Accordingly, the absorber material of the invention may comprise from 0 to 70% by weight, preferably from 0 to 30% by weight, of other additives.

Additives may be sterically hindered phenols. Suitable sterically hindered phenols are in principle any of the compounds having a phenolic structure and having at least one bulky group on the phenolic ring.

Examples of compounds whose use is preferred are those of the formula

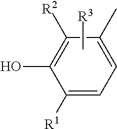

where: R¹ and R² are alkyl, substituted alkyl or a substituted triazole group, where R¹ and R² may be identical or different, and R³ is alkyl, substituted alkyl, alkoxy or substituted amino.

Antioxidants of the type mentioned are described, for example, in DE-A 27 02 661 (U.S. Pat. No. 4,360,617).

Another group of preferred sterically hindered phenols derives from substituted benzenecarboxylic acids, in particular from substituted benzenepropionic acids.

Particularly preferred compounds of this class have the formula

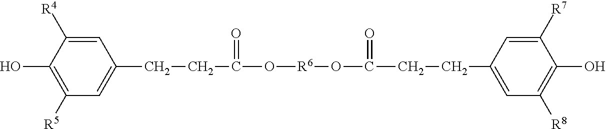

where R⁴, R⁵, R⁷ and R⁸, independently of one another, are C₁-C₈-alkyl which may in turn have substitution (at least one of these is a bulky group) and R⁶ is a bivalent aliphatic radical which has from 1 to 10 carbon atoms and may also have C—O bonds in its main chain. Preferred compounds are

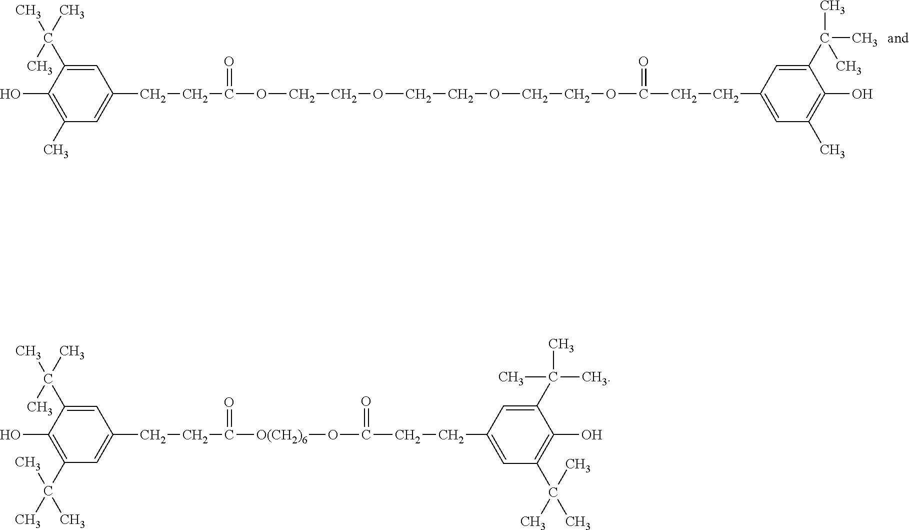

The examples of sterically hindered phenols which should be mentioned are: 2,2′-methylenebis(4-methyl-6-tert-butylphenol), 1,6-hexanediol bis[3-(3,5-di-tert-butyl-4-hydroxyphenyl)propionate], pentaerythritol tetrakis[3-(3,5-di-tert-butyl-4-hydroxyphenyl)propionate], distearyl 3,5-di-tert-butyl-4-hydroxybenzylphosphonate, 2,6,7-trioxa-1-phosphabicyclo[2.2.2]oct-4-ylmethyl 3,5-di-tert-butyl-4-hydroxyhydrocinnamate, 3,5-di-tertbutyl-4-hydroxyphenyl-3,5-distearylthiotriazylamine, 2-(2′-hydroxy-3′-hydroxy-3′,5′-di-tertbutylphenyl)-5-chlorobenzotriazole-, 2,6-di-tert-butyl-4-hydroxymethylphenol, 1,3,5-trimethyl-2,4,6-tris(3,5-di-tert-butyl-4-hydroxybenzyl)benzene, 4,4′-methylenebis(2,6-di-tert-butylphenol), 3,5-di-tert-butyl-4-hydroxybenzyldimethylamine and N,N′-hexamethylenebis-3,5-di-tert-butyl-4-hydroxyhydrocinnamide.

Compounds which have proven especially effective and which are therefore preferably used are 2,2′-methylenebis(4-methyl-6-tert-butylphenyl), 1,6-hexanediol bis(3,5-di-tert-butyl-4-hydroxyphenyl]propionate, pentaerythritol tetrakis[3-(3,5-di-tert-butyl-4-hydroxyphenyl)propionate].

The amounts present of the antioxidants as additives-if present-, which may be used individually or as mixtures, are usually up to 2% by weight, preferably from 0.005 to 2% by weight, in particular from 0.1 to 1% by weight, based on the total weight of the absorber material.

Sterically hindered phenols which have proven particularly advantageous, in particular when assessing color stability on storage in diffuse light over prolonged periods, in some cases have no more than one sterically hindered group in the ortho position to the phenolic hydroxyl.

The polyamides which can be used as additives are known per se. Use may be made of partly crystalline or amorphous resins as described, for example, in the Encyclopedia of Polymer Science and Engineering, Vol. 11, John Wiley & Sons, Inc., 1988, pp. 315 489. The melting point of the polyamide here is preferably below 225° C., and particularly preferably below 215° C.

Examples of these are polyhexamethylene azelamide, polyhexamethylene sebacamide, polyhexamethylene dodecanediamide, poly-11-aminoundecanamide and bis(p-aminocyclohexyl)methyldodecanediamide, and the products obtained by ring-opening of lactams, for example polylaurolactam. Other suitable polyamides are based on terephthalic or isophthalic acid as acid component and trimethylhexamethylenediamine or bis(p-aminocyclohexyl)propane as diamine component and polyamide base resins prepared by copolymerizing two or more of the abovementioned polymers or components thereof.

Particularly suitable polyamides which may be mentioned are copolyamides based on caprolactam, hexamethylenediamine, p,p′-diaminodicyclohexylmethane and adipic acid. An example of these is the product marketed by BASF SE under the name Ultramid® 1 C.

Other suitable polyamides are marketed by Du Pont under the name Elvamide®.

The preparation of these polyamides is also described in the abovementioned text. The ratio of terminal amino groups to terminal acid groups can be controlled by varying the molar ratio of the starting compounds.

The proportion of the polyamide in the molding composition of the invention is up to 2% by weight, by preference from 0.005 to 1.99% by weight, preferably from 0.01 to 0.08% by weight.

The dispersibility of the polyamides used can be improved in some cases by concomitant use of a polycondensation product made from 2,2-di(4-hydroxyphenyl)propane (bisphenol A) and epichlorohydrin.

Condensation products of this type made from epichlorohydrin and bisphenol A are commercially available. Processes for their preparation are also known to the person skilled in the art. The molecular weight of the polycondensates can vary within wide limits. In principle, any of the commercially available grades is suitable.

Other stabilizers which may be present as additives are one or more alkaline earth metal silicates and/or alkaline earth metal glycerophosphates in amounts of up to 2.0% by weight, preferably from 0.005 to 0.5% by weight and in particular from 0.01 to 0.3% by weight, based on the total weight of the absorber material. Alkaline earth metals which have proven preferable for forming the silicates and glycerophosphates are calcium and, in particular, magnesium. Useful compounds are calcium glycerophosphate and preferably magnesium glycerophosphate and/or calcium silicate and preferably magnesium silicate. Particularly preferable alkaline earth silicates here are those described by the formula Me.xSiO₂.nH₂O where: Me is an alkaline earth metal, preferably calcium or in particular magnesium, x is a number from 1.4 to 10, preferably from 1.4 to 6, and n is greater than or equal to 0, preferably from 0 to 8.

The compounds are advantageously used in finely ground form. Particularly suitable products have an average particle size of less than 100 μm, preferably less than 50 μm.

Preference is given to the use of calcium silicates and magnesium silicates and/or calcium glycerophosphates and magnesium glycerophosphates. Examples of these may be defined more precisely by the following characteristic values:

Calcium silicate and magnesium silicate, respectively: content of CaO and MgO, respectively: from 4 to 32% by weight, preferably from 8 to 30% by weight and in particular from 12 to 25% by weight, ratio of SiO₂ to CaO and SiO₂ to MgO, respectively (mol/mol): from 1.4 to 10, preferably from 1.4 to 6 and in particular from 1.5 to 4, bulk density: from 10 to 80 g/100 ml, preferably from 10 to 40 g/100 ml, and average particle size: less than 100 μm, preferably less than 50 μm.

Calcium glycerophosphates and magnesium glycerophosphates, respectively: content of CaO and MgO, respectively: above 70% by weight, preferably above 80% by weight, residue on ashing: from 45 to 65% by weight, melting point: above 300° C., and average particle size: less than 100 μm, preferably less than 50 μm.

Preferred lubricants as additives which may be present in the absorber material of the present invention are, in amounts of up to 5, preferably from 0.09 to 2 and in particular from 0.1 to 0.7% by weight, at least one ester or amide of saturated or unsaturated aliphatic carboxylic acids having from 10 to 40 carbon atoms, preferably from 16 to 22 carbon atoms, with polyols or with saturated aliphatic alcohols or amines having from 2 to 40 carbon atoms, preferably from 2 to 6 carbon atoms, or with an ether derived from alcohols and ethylene oxide.

The carboxylic acids may be mono- or dibasic. Examples which may be mentioned are pelargonic acid, palmitic acid, lauric acid, margaric acid, dodecanedioic acid, behenic acid and, particularly preferably, stearic acid, capric acid and also montanic acid (a mixture of fatty acids having from 30 to 40 carbon atoms).

The aliphatic alcohols may be mono- to tetrahydric. Examples of alcohols are n-butanol, n-octanol, stearyl alcohol, ethylene glycol, propylene glycol, neopentyl glycol and pentaerythritol, and preference is given to glycerol and pentaerythritol.

The aliphatic amines may be mono- to tribasic. Examples of these are stearylamine, ethylenediamine, propylenediamine, hexamethylenediamine and di(6-aminohexyl)amine, and particular preference is given to ethylenediamine and hexamethylenediamine. Correspondingly, preferred esters and amides are glycerol distearate, glycerol tristearate, ethylenediammonium distearate, glycerol monopalmitate, glycerol trilaurate, glycerol monobehenate and pentaerythritol tetrastearate.

It is also possible to use mixtures of different esters or amides or esters with amides combined, in any desired mixing ratio.

Other suitable compounds are polyether polyols and polyester polyols which have been esterified with mono- or polybasic carboxylic acids, preferably fatty acids, or have been etherified. Suitable products are available commercially, for example Loxiol® EP 728 from Henkel KGaA.

Preferred ethers, derived from alcohols and ethylene oxide, have the formula RO(CH₂CH₂O)ₙH where R is alkyl having from 6 to 40 carbon atoms and n is an integer greater than or equal to 1.

R is particularly preferably a saturated C₁₆ to C₁₈ fatty alcohol with n of about 50, obtainable commercially from BASF as Lutensol® AT 50.

The absorber material of the present invention may comprise from 0 to 5%, preferably from 0.001 to 5% by weight, particularly preferably from 0.01 to 3% by weight and in particular from 0.05 to 1% by weight, of a melamine-formaldehyde condensate. This is preferably a crosslinked, water-insoluble precipitation condensate in finely divided form. The molar ratio of formaldehyde to melamine is preferably from 1.2:1 to 10:1, in particular from 1.2:1 to 2:1. The structure of condensates of this type and processes for their preparation are found in DE-A 25 40 207.

The absorber material of the present invention may comprise from 0.0001 to 1% by weight, preferably from 0.001 to 0.8% by weight, and in 10 particular from 0.01 to 0.3% by weight, of a nucleating agent as additive.

Possible nucleating agents are any known compounds, for example melamine cyanurate, boron compounds, such as boron nitride, silica, pigments, e.g. Heliogenblue (copper phthalocyanine pigment; registered trademark of BASF SE), or branched polyoxymethylenes, which in these small amounts have a nucleating action.

Talc in particular is used as a nucleating agent and is a hydrated magnesium silicate of the formula Mg₃[(OH)₂/Si₄O₁₀] or MgO.4SiO₂.H₂O. This is termed a three-layer phyllosilicate and has a triclinic, monoclinic or rhombic crystal structure and a lamella appearance. Other trace elements which may be present are Mn, Ti, Cr, Ni, Na and K, and some of the OH groups may have been replaced by fluoride.

Particular preference is given to the use of talc in which 100% of the particle sizes are <20 μm. The particle size distribution is usually determined by sedimentation analysis and is preferably:

<20 μm 100% by weight
<10 μm 99% by weight
<5 μm 85% by weight
<3 μm 60% by weight
<2 μm 43% by weight

Products of this type are commercially available as Micro-Talc I.T. extra (Norwegian Talc Minerals).

Examples of fillers which may be mentioned, in amounts of up to 50% by weight, preferably from 5 to 40% by weight, are potassium titanate whiskers, carbon fibers and preferably glass fibers. The glass fibers may, for example, be used in the form of glass wovens, mats, nonwovens and/or glass filament rovings or chopped glass filaments made from low-alkali E glass and having a diameter of from 5 to 200 μm, preferably from 8 to 50 μm. After they have been incorporated, the fibrous fillers preferably have an average length of from 0.05 to 1 μm, in particular from 0.1 to 0.5 μm.

Examples of other suitable fillers are calcium carbonate and glass beads, preferably in ground form, or mixtures of these fillers.

Other additives which may be mentioned are amounts of up to 50% by weight, preferably from 0 to 40% by weight, of impact-modifying polymers (also referred to below as elastomeric polymers or elastomers).

Preferred types of such elastomers are those known as ethylene-propylene (EPM) and ethylene-propylene-diene (EPDM) rubbers.

EPM rubbers generally have practically no residual double bonds, whereas EPDM rubbers may have from 1 to 20 double bonds per 100 carbon atoms.

Examples which may be mentioned of diene monomers for EPDM rubbers are conjugated dienes, such as isoprene and butadiene, non-conjugated dienes having from 5 to 25 carbon atoms, such as 1,4-pentadiene, 1,4-hexadiene, 1,5-hexadiene, 2,5-dimethyl-1,5-hexadiene and 1,4-octadiene, cyclic dienes, such as cyclopentadiene, cyclohexadienes, cyclooctadienes and dicyclopentadiene, and also alkenylnorbornenes, such as 5-ethylidene-2-norbornene, 5-butylidene-2-norbornene, 2-methallyl-5-norbornene and 2-isopropenyl-5-norbornene, and tricyclodienes, such as 3-methyl-tricyclo[5.2.1.0.2.6]-3,8-decadiene, or mixtures of these. Preference is given to 1,5-hexadiene-5-ethylidenenorbornene and dicyclopentadiene. The diene content of the EPDM rubbers is preferably from 0.5 bis 50% by weight, in particular from 1 to 8% by weight, based on the total weight of the rubber.

EPOM rubbers may preferably have also been grafted with other monomers, e.g. with glycidyl (meth)acrylates, with (meth)acrylic esters, or with (meth)acrylamides.

Copolymers of ethylene with esters of (meth)acrylic acid are another group of preferred rubbers. The rubbers may also contain monomers having epoxy groups. These monomers containing epoxy groups are preferably incorporated into the rubber by adding, to the monomer mixture, monomers having epoxy groups and the formula I or II

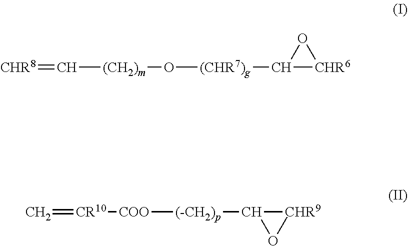

where R⁶ to R¹⁰ are hydrogen or alkyl having from 1 to 6 carbon atoms, and m is an integer from 0 to 20, g is an integer from 0 to 10 and p is an integer from 0 to 5.

R⁶ to R⁸ are preferably hydrogen, where m is 0 or 1 and g is 1. The corresponding compounds are allyl glycidyl ether and vinyl glycidyl ether.

Preferred compounds of the formula II are acrylic and/or methacrylic esters having epoxy groups, for example glycidyl acrylate and glycidyl methacrylate.

The copolymers are advantageously composed of from 50 to 98% by weight of ethylene, from 0 to 20% by weight of monomers having epoxy groups, the remainder being (meth)acrylic esters.

Particular preference is given to copolymers made from from 50 to 98% by weight, in particular from 55 to 95% by weight, of ethylene, in particular from 0.3 to 20% by weight of glycidyl acrylate, and/or from 0 to 40% by weight, in particular from 0.1 to 20% by weight, of glycidyl methacrylate, and from 1 to 50% by weight, in particular from 10 to 40% by weight, of n-butyl acrylate and/or 2-ethylhexyl acrylate.

Other preferred (meth)acrylates are the methyl, ethyl, propyl, isobutyl and tert-butyl esters. Besides these, comonomers which may be used are vinyl esters and vinyl ethers.

The ethylene copolymers described above may be prepared by processes known per se, preferably by random copolymerization at high pressure and elevated temperature. Appropriate processes are well known.

Preferred elastomers also include emulsion polymers whose preparation is described, for example, by Blackley in the monograph “Emulsion Polymerization”. The emulsifiers and catalysts which may be used are known per se.

In principle it is possible to use homogeneously structured elastomers or those with a shell construction. The shell-type structure is determined, inter alia, by the sequence of addition of the individual monomers. The morphology of the polymers is also affected by this sequence of addition.

Monomers which may be mentioned here, merely as examples, for the preparation of the rubber fraction of the elastomers are acrylates, such as n-butyl acrylate and 2-ethylhexyl acrylate, and corresponding methacrylates, and butadiene and isoprene, and also mixtures of these. These monomers may be copolymerized with other monomers, such as styrene, acrylonitrile, vinyl ethers and with other acrylates or methacrylates, such as methyl methacrylate, methyl acrylate, ethyl acrylate or propyl acrylate.

The soft or rubber phase (with a glass transition temperature of below 0° C.) of the elastomers may be the core, the outer envelope or an intermediate shell (in the case of elastomers whose structure has more than two shells). When elastomers have more than one shell it is also possible for more than one shell to be composed of a rubber phase.

If one or more hard components (with glass transition temperatures above 20° C.) are involved, besides the rubber phase, in the structure of the elastomer, these are generally prepared by polymerizing, as principal monomers, styrene, acrylonitrile, methacrylonitrile. alpha.methylstyrene, p-methylstyrene, or acrylates or methacrylates, such as methyl acrylate, ethyl acrylate or ethyl methacrylate. Besides these, it is also possible to use relatively small proportions of other comonomers.

It has proven advantageous in some cases to use emulsion polymers which have reactive groups at their surfaces. Examples of groups of this type are epoxy, amino and amide groups, and also functional groups which may be introduced by concomitant use of monomers of the formula

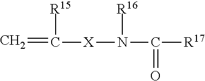

where: R¹⁵ is hydrogen or C₁- to C₄-alkyl, R₁₆ is hydrogen, C₁- to C₈-alkyl or aryl, in particular phenyl, R¹⁷ is hydrogen, C₁- to C₁₀-alkyl, C₆- to C₁₂-aryl or —OR¹⁸.

R¹⁸ is C₁- to C₈-alkyl or C₆- to C₁₂-aryl, if desired with substitution by O- or N-containing groups, X is a chemical bond, C₁- to C₁₀-alkylene or C₆- to C₁₂-aryl, or

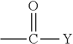

The graft monomers described in EP-A 208 187 are also suitable for introducing reactive groups at the surface.

Other examples which may be mentioned are acrylamide, methacrylamide and substituted acrylates or methacrylates, such as (N-tert-butylamino)ethyl methacrylate, (N,N-dimethylamino)ethyl acrylate, (N,N-dimethylamino)methyl acrylate and (N,N-diethylamino)ethyl acrylate.

The particles of the rubber phase may also have been crosslinked. Examples of crosslinking monomers are 1,3-butadiene, divinylbenzene, diallyl phthalate, butanediol diacrylate and dihydrodicyclopentadienyl acrylate, and also the compounds described in EP A 50 265.

It is also possible to use the monomers known as graft-linking monomers, i.e. monomers having two or more polymerizable double bonds which react at different rates during the polymerization. Preference is given to the use of those compounds in which at least one reactive group polymerizes at about the same rate as the other monomers, while the other reactive group (or reactive groups), for example, polymerize(s) significantly more slowly. The different polymerization rates give rise to a certain proportion of unsaturated double bonds in the rubber. If another phase is then grafted onto a rubber of this type, at least some of the double bonds present in the rubber react with the graft monomers to form chemical bonds, i.e. the phase grafted on has at least some degree of chemical bonding to the graft base.

Examples of graft-linking monomers of this type are monomers containing allyl groups, in particular allyl esters of ethylenically unsaturated carboxylic acids, for example allyl acrylate, allyl methacrylate, diallyl maleate, diallyl fumarate and diallyl itaconate, and the corresponding monoallyl compounds of these dicarboxylic acids. Besides these there is a wide variety of other suitable graft-linking monomers. For further details reference may be made here, for example, to U.S. Pat. No. 4,148,846.

The proportion of these crosslinking monomers is generally up to 5% by weight, preferably not more than 3% by weight, based on the total amount of additives.

Some preferred emulsion polymers are listed below. Mention is made firstly of graft polymers with a core and with at least one outer shell and the following structure:

| | |
|---|---|
| Monomers for the core | Monomers for the envelope |
| 1,3-butadiene, isoprene, | Styrene, acrylonitrile, |
| n-butyl acrylate, ethylhexyl- | (meth)acrylate, where appropri- |
| acrylate or a mixture of these, | ate having reactive groups, as |
| where appropriate together with | described herein |
| crosslinking monomers | |

Instead of graft polymers whose structure has more than one shell it is also possible to use homogeneous, i.e. single-shell, elastomers made from 1,3-butadiene, isoprene and n-butyl acrylate or from copolymers of these. These products, too, may be prepared by concomitant use of crosslinking monomers or of monomers having reactive groups.

The elastomers described as additives may also be prepared by other conventional processes, e.g. by suspension polymerization.

Other suitable elastomers which may be mentioned are thermoplastic polyurethanes, as described in EP-A 115 846, EP-A 115 847, and EP-A 117 664, for example.

It is, of course, also possible to use mixtures of the rubber types listed above.

The absorber material of the present invention may also comprise other conventional additives and processing aids. Merely by way of example, mention may be made here of additives for scavenging formaldehyde (formaldehyde scavengers), plasticizers, coupling agents, and pigments. The proportion of additives of this type is generally within the range from 0.001 to 5% by weight.

The absorber material of the present invention shows good (high) absorption and good (low) reflection. Thus, preferably the absorber material shows at least 70% absorption and less than 30% reflection. Furthermore, the absorber material of the present invention can have a melt volume rate of 120 cm³/10 min to 5 cm³/10 min measured at 250° C./min with a weight of 2.16 kg.

The wave absorber of the present invention can be used for absorbing electromagnetic waves in the above mentioned frequency region or range.

Accordingly, another aspect of the present invention is an electronic device containing a radar absorber in form of a radar absorber part or a radar absorbing housing, the radar absorber comprising
at least an absorber material of the present invention, wherein the at least one absorber material is comprised in the electronic device in the radar absorber;
at least one transmission area, transmissible for electromagnetic millimeter waves in a frequency region of 60 GHz or more; and
a sensor capable of detecting and optionally emitting electromagnetic millimeter waves in a frequency region of 60 GHz or more through the transmission area.

The absorber material and electronic device of the present invention are especially suitable for autonomous driving and thus forms part of a vehicle, like a car, a bus or a heavy goods vehicle, or telecommunication, 5G, anechoic chambers.

The following examples and FIGURE explain the invention in further details without limiting the invention to these.

In the FIGURE the following is shown:

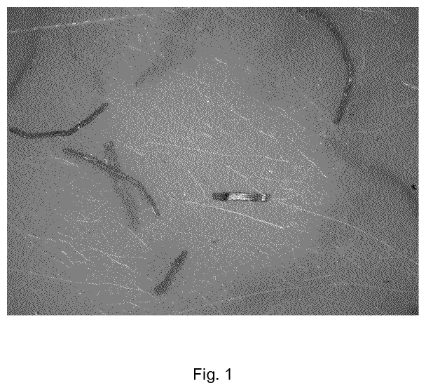

FIG. 1 shows the stainless-steel fibers in example C4

### EXAMPLES

### Materials

Poly(butylene terephthalate) (PBT, Ultradur® B2550 NAT and B4500 NAT) were obtained from BASF SE. Carbon fibers (aspect ratio >5) were obtained from Toho Tenax. Black pearls 880 (aspect ratio <5) were obtained from Cabot corporation and special black 4 (aspect ratio <5) was obtained from Orion Engineered Carbon. The stainless-steel fiber (stainless steel 1.4113) with a broad length distribution including particles with aspect ratio >5) was obtained from Deutsche Metallfaserwerk. Glass fibers were obtained from 3B.

Measurement of the Interaction with Electromagnetic Waves

The experimental setup for the characterization of the absorbers in the range 60-90 GHz is as follows.

A vectoral network analyzer Keysight N5222A (10 MHz-26.5 GHz), two Keysight T/R mm head modules N5256AW12, 60-90 GHz and as a sample holder a swisstol2 corrugated waveguide WR12+, 55-90 GHz. The calibration of the corrugated waveguide (cw) is done by doing a thru and short measurement. For the thru measurements the flanges of the cw are connected, for the short measurement, a metal plate is inserted between the flanges. The field distribution of the cw is described in: IEEE Transactions on Microwave Theory and Techniques 58, 11 (2010), 2772.

After the calibration, the sample (minimum diameter 2 cm) is inserted between the flanges of the cw and the S11 (reflection) and S21 (transmission) parameters are measured in the range 60-90 GHz (amplitude and phase). From the measured S11 and S22 parameters, the absorption A of the sample was calculated as follows: A (%)=100−S11(%)−S21(%).

From the measured parameters, the dielectric parameters ε′ (dielectric permittivity) and ε″ (dielectric loss factor) of the sample material is calculated at each frequency point using the swissto12 materials measurement software.

### Preparation of the Comparative Example C4

Poly(butylene terephthalate) (PBT, Ultradur® B4500 NAT) was obtained from BASF SE and dried to a water content below 0.04 wt %. The PBT was fed into to extruder (ZE25) with a barrel temperature of 270° C. and an output of 15 kg/h. Steel fibers were added directly in the melt in zone 4 of the extruder to prevent excessive shearing of the fibers. Material was granulated and dried to a water content below 0.04 wt %. The samples for the electromagnetic analysis (60×60×1.5 mm) were injection molded using 260° C. for melt temperature, 60° C. for mold temperature.

The composition of the examples containing carbon fibers (I1-2) and the comparative example (C0-C3) have been stated in Table 1 (a and b). In Table 2 materials containing metal fibers (I3-4) and comparative examples (C4) are shown.

TABLE 1a
Compositions of the comparative examples with carbon fibers

| | | comparative examples | | | |
|---|---|---|---|---|---|
| | | C0 | C1 | C2 | C3 |
| PBT resin | % | 100 | 79.5 | 39.5 | 29.5 |
| (Ultradur B2550 NAT) | | | | | |
| Glass fiber (average diam. 10 | % | | 20 | 20 | 20 |
| μm with epoxysilane sizing) | | | | | |
| Carbon black batch (20% | % | | | 40 | 50 |
| carbon black Black-Pearls | | | | | |
| 880-in PBT) | | | | | |
| Carbon fiber batch (15% | % | | | | |
| carbon fibers-in PBT) | | | | | |
| Lubricant (C16-C18 fatty | % | | 0.5 | 0.5 | 0.5 |
| esters of pentaerythritol) | | | | | |
| radar absorption at 77 GHz | % | 6 | 8 | 58 | 69 |
| for 2 mm thick samples | | | | | |
| Dielectric permittivity at | | 2.97 | 3.35 | 5.15 | 6.15 |
| 77 GHz tensile E-modulus | MPa | 2500 | 7000 | 7800 | 8000 |
| tensile strength | MPa | 57 | 117 | 117 | 116 |
| elongation at break | % | 35 | 3.5 | 2.4 | 2.0 |

TABLE 2b
Compositions of the examples with carbon fibers

| | | inventive examples | |
|---|---|---|---|
| | | I1 | I2 |
| PBT resin (Ultradur B2550 NAT) | % | 38,5 | 37,5 |
| Glass fiber (average diam. 10μm with | % | 20 | 20 |
| epoxysilane sizing) | | | |
| Carbon black batch (20% carbon | % | 40 | 40 |
| black Black - Pearls 880 - in PBT) | | | |
| Carbon fiber batch (15% carbon fibers | % | 1 | 2 |
| - - in PBT) | | | |
| Lubricant (C16-C18 fatty esters of | % | 0.5 | 0.5 |
| pentaerythritol) | | | |
| radar absorption at 77 GHz for 2 mm | % | 66 | 73 |
| thick samples | | | |
| Dielectric permittivity at 77 GHz | | 6,52 | 7,46 |
| tensile E-modulus | MPa | 7950 | 8050 |
| tensile strength | MPa | 116 | 116 |
| elongation at break | % | 2,4 | 2,4 |

TABLE 2
Compositions of the examples and comparative examples containing metal fibers

| | | comparative examples | | Inventive examples | |
|---|---|---|---|---|---|
| | | C0 | C4 | I3 | I4 |
| PBT resin (Ultradur B4500 NAT) | % | 99.5 | 93.5 | 91.5 | 89.5 |
| Lubricant (C16-C18 fatty esters of | | | | | |
| pentaerythritol) | % | 0.5 | 0.5 | 0.5 | 0.5 |
| carbon black batch (25% carbon black | | | | | |
| Special black 4 - in PBT) | % | | | 2 | 4 |
| Stainless steel fiber | % | | 6 | 6 | 6 |
| Radar absorption at 77 GHz for 1,5 | | | | | |
| mm samples | % | 4 | 78 | 82 | 87 |
| Dielectric permittivity at 77 GHz | | 2,97 | 4,77 | 4,40 | 4,06 |

1. An electromagnetic millimetre wave absorber material containing solid particles having an aspect ratio (length:diameter) of at least 5 of a first electrically conductive material, particles having an aspect ratio (length:diameter) of less than 5 of a second electrically conductive material and an electrically non-conductive polymer, wherein the absorber material is capable of absorbing electromagnetic waves in a frequency region of 60 GHz or more.

2. The absorber material of claim 1, wherein the solid particles having an aspect ratio (length:diameter) of at least 5 of the first electrically conductive material are solid fibre particles having an acicular or cylindrical shape or a turned chip like shape.

3. The absorber material of claim 1, wherein the particles having an aspect ratio (length:diameter) of less than 5 of a second electrically conductive material are non-fibrous particles having a spherical or lamellar shape.

4. The absorber material of claim 1, wherein the electrically non-conductive polymer is a thermoplast, a thermoplastic elastomer, a thermoset, or a vitrimer.

5. The absorber material of claim 1, wherein the particles of the first and second electrically conductive material are homogenously distributed in the absorber material.

6. The absorber material of claim 1, wherein the absorber material is subject to injection molding, thermoforming, compression molding, or 3D printing.

7. The absorber material of claim 1, wherein an amount of the particles of the first and second electrically conductive material is from 0.05 wt.-% to 24.95 wt.-% based on the total amount of the absorber material.

8. The absorber material of claim 1, wherein an amount of the particles of the second electrically conductive material is from 0.05 wt.-% to 15 wt.-% based on the total amount of the absorber material.

9. The absorber material of claim 1, wherein the first or the second or the first and the second electrically conductive material are carbon or a metal.

10. The absorber material of claim 9, wherein the metal is zinc, nickel, copper, tin, cobalt, manganese, iron, magnesium, lead, chromium, bismuth, silver, gold, aluminum, titanium, palladium, platinum, tantalum, or an alloy thereof.

11. The absorber material of claim 1, wherein the first and the second electrically conductive material is the same.

12. The absorber material of claim 1, wherein at least one of the following prerequisites is fulfilled:
the first and the second electrically conductive material is carbon;
the first electrically conductive material is iron or steel and the second conductive material is carbon;
the particles of the second electrically conductive material are carbon black;
the iron or iron alloy material is stainless steel;
the particles of the first electrically conductive material have a length of from 0.01 to 100 mm;
the particles of the first electrically conductive material have a diameter of from 0.1 μm to 100 μm.

13. The absorber material of claim 1, wherein the absorber material additionally contains one or more additives.

14. An electronic device containing a radar absorber in form of a radar absorber part or a radar absorbing housing, the radar absorber comprising
at least an absorber material of claim 1, wherein the at least one absorber material is comprised in the electronic device in the radar absorber;
at least one transmission area, transmissible for electromagnetic millimeter waves in a frequency region of 60 GHz or more; and
a sensor capable of detecting and optionally emitting electromagnetic millimeter waves in a frequency region of 60 GHz or more through the transmission area.

15. (canceled)

16. A method of absorbing electromagnetic millimeter waves in a frequency region of 60 GHz or more, the method comprising irradiating an absorber material of claim 1 with electromagnetic millimeter waves in a frequency region of 60 GHz or more.

17. The absorber material of claim 1 having a volume resistivity of more than 1 Ωcm.
